(19) United States
(12) Patent Application Publication
(10) Pub. No.: US 2026/0334102 A1
(43) Pub. Date: Oct. 22, 2026

(54) OHMIC REGROWTH MASKING METHOD AND STRUCTURE

(71) Applicant: Raytheon Company, Arlington, VA (US)

(72) Inventors: John A. Logan, Lawrence, MA (US); Clay T. Long, Tewksbury, MA (US); Jeffrey R. LaRoche, Austin, TX (US)

(21) Appl. No.: 19/185,036

(22) Filed: Apr. 21, 2025

(51) Int. Cl. H10P 14/20; H10D 62/85; H10P 50/64

(52) U.S. Cl. CPC H10P 14/27; H10D 62/8503; H10P 14/3416; H10P 50/646

(57) ABSTRACT

A method includes forming a single gallium-nitride (GaN) layer over a structure. The structure includes a polarity-switching layer and at least one hole through at least the polarity-switching layer. The single GaN layer includes a nitrogen-polar (N-polar) GaN region over the polarity-switching layer and a gallium-polar (Ga-polar) GaN region within the at least one hole. The N-polar GaN region may be removed from the structure while the Ga-polar GaN region remains.

### TECHNICAL FIELD

This disclosure relates generally to ohmic regrowth systems and processes. More specifically, this disclosure relates to an ohmic regrowth masking method and structure.

### BACKGROUND

Ohmic regrowth methods typically involve applying a dielectric hardmask over the surface of a wafer, after which a doped N-type gallium-nitride (N+GaN) layer is grown over areas exposed by the hardmask as well as on top of the hardmask. However, the use of a conventional dielectric hardmask in this process results in undesirable polycrystalline regions of N+GaN on top of the hardmask, which are difficult to remove. In addition, the standard practice for removing these polycrystalline regions often unintentionally etches alignment marks elsewhere on the wafer.

### SUMMARY

This disclosure relates to an ohmic regrowth masking method and structure.

In a first embodiment, a method may include forming a single gallium-nitride (GaN) layer over a structure. The structure may include a polarity-switching layer and at least one hole through at least the polarity-switching layer. The single GaN layer may include a nitrogen-polar (N-polar) GaN region over the polarity-switching layer and a gallium-polar (Ga-polar) GaN region within the at least one hole. The N-polar GaN region may be removed from the structure while the Ga-polar GaN region remains.

Any single one or any combination of the following features may be used with the first embodiment. The polarity-switching layer may include niobium nitride (NbN) or tantalum nitride (TaN). The GaN layer may include N+GaN doped with silicon or germanium. Removing the N-polar GaN region may include removing the N-polar GaN region by a wet etching process. The polarity-switching layer may be removed. The structure may be formed on a wafer that includes alignment marks. Removing the N-polar GaN region from the structure may include removing the N-polar GaN region without etching the alignment marks.

In a second embodiment, a method may include providing an initial structure. A polarity-switching layer may be formed over the initial structure. At least one hole may be formed through at least the polarity-switching layer. A single layer including a specified material may be formed within the at least one hole and over the polarity-switching layer. The specified material may include a first polarity within the at least one hole and a second polarity over the polarity-switching layer. The specified material including the second polarity may be configured to be selectively removable without affecting the specified material including the first polarity.

Any single one or any combination of the following features may be used with the second embodiment. The polarity-switching layer may include NbN or TaN. The specified material may include a Group III-nitride. The Group III-nitride may include GaN. The first polarity may include Ga-polar, and the second polarity may include N-polar. The Group III-nitride may include N+GaN doped with silicon or germanium. The method may include removing the specified material that includes the second polarity by a wet etching process. The method may include removing the polarity-switching layer. Providing the initial structure may include providing the initial structure on a wafer that includes alignment marks. The specified material including the second polarity may be configured to be selectively removable without etching the alignment marks.

In a third embodiment, a structure may include a Ga-polar GaN layer formed on a wafer. A III-Nitride barrier layer may be formed over the Ga-polar GaN layer. A polarity-switching layer may be formed over the III-Nitride barrier layer. At least one hole may be formed through at least the polarity-switching layer. A single layer may be formed within the at least one hole and over the polarity-switching layer. The single layer may include a first-polarity region within the at least one hole and a second-polarity region over the polarity-switching layer.

Any single one or any combination of the following features may be used with the third embodiment. The single layer may include a Group III-nitride. The single layer may include GaN, the first-polarity region may include Ga-polar GaN, and the second-polarity region may include N-polar GaN. The single layer may include N+GaN doped with silicon or germanium. The polarity-switching layer may include NbN or TaN.

Other technical features may be readily apparent to one skilled in the art from the following figures, descriptions, and claims.

### BRIEF DESCRIPTION OF THE DRAWINGS

For a more complete understanding of this disclosure, reference is made to the following description, taken in conjunction with the accompanying drawings, in which:

FIGS. 1A-1D are a series of schematic cross-sectional diagrams illustrating an example process of ohmic regrowth masking according to this disclosure;

FIG. 2 is a schematic cross-sectional diagram illustrating an example structure formed using ohmic regrowth masking according to this disclosure;

FIG. 3 is a schematic cross-sectional diagram illustrating another example structure formed using ohmic regrowth masking according to this disclosure; and

FIG. 4 illustrates an example of a method for providing ohmic regrowth masking according to this disclosure.

### DETAILED DESCRIPTION

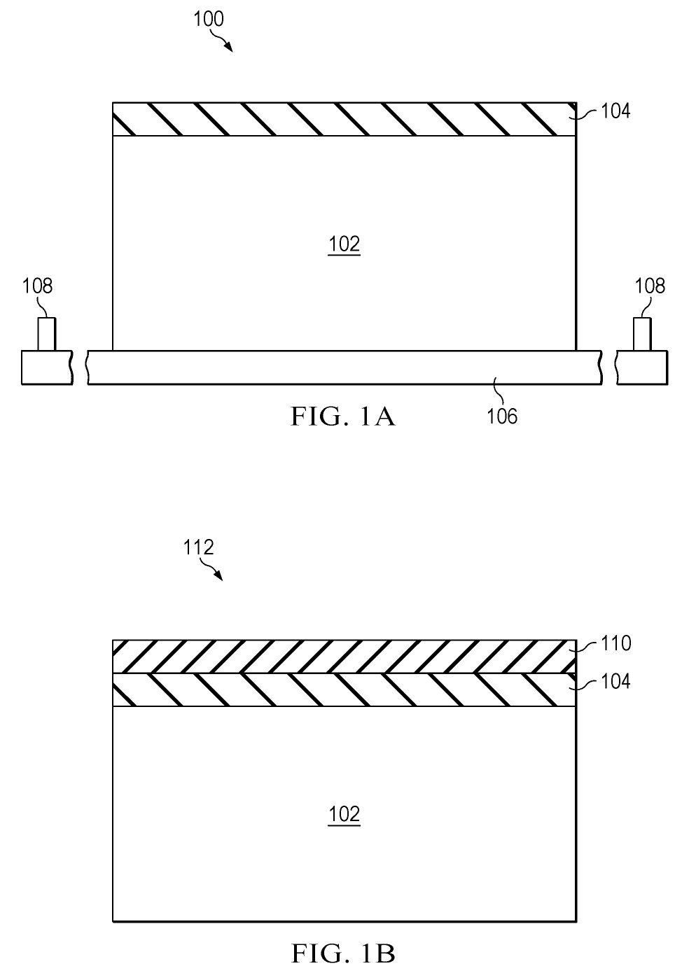

FIGS. 1A through 4, described below, and the various embodiments used to describe the principles of the present disclosure are by way of illustration only and should not be construed in any way to limit the scope of this disclosure. Those skilled in the art will understand that the principles of the present disclosure may be implemented in any type of suitably arranged device or system.

As noted above, ohmic regrowth methods typically involve applying a dielectric hardmask over the surface of a wafer, after which a doped N-type gallium-nitride (N+GaN) layer is grown over areas exposed by the hardmask as well as on top of the hardmask. However, the use of a conventional dielectric hardmask in this process results in undesirable polycrystalline regions of N+GaN on top of the hardmask, which are difficult to remove. In addition, the standard practice for removing these polycrystalline regions often unintentionally etches alignment marks elsewhere on the wafer.

This disclosure provides ohmic regrowth masking methods and structures. As described in more detail below, in some embodiments, a single GaN layer can be formed over a structure. The structure can include a polarity-switching layer and a plurality of holes through at least the polarity-switching layer. The single GaN layer can include a nitrogen-polar (N-polar) GaN region over the polarity-switching layer and a gallium-polar (Ga-polar) GaN region within the holes. The N-polar GaN region can be removed from the structure, while the Ga-polar GaN region remains. Thus, ohmic regrowth may be provided without the need for a dielectric hardmask and the corresponding long liftoff-based etch to remove unwanted polycrystalline GaN. Instead, the use of a polarity-switching layer allows for the single GaN layer to include N-polar GaN in a region where the GaN is to be removed and Ga-polar GaN where the GaN is to remain part of the structure. Because N-polar GaN is several orders of magnitude more reactive than Ga-polar GaN, the polarity-switching layer both eliminates the need for the dielectric hardmask and provides for a quicker process. In addition, in some embodiments, unintentional etching of other components of the structure can be prevented.

FIGS. 1A-1D are a series of schematic cross-sectional diagrams illustrating an example process of ohmic regrowth masking according to this disclosure. The embodiment of the process shown in FIGS. 1A-1D is for illustration only. Other embodiments of the process may be used without departing from the scope of this disclosure.

Referring to FIG. 1A, an initial structure 100 is provided that can include a Ga-polar GaN layer 102 and a III-Nitride barrier layer 104. The III-Nitride barrier layer 104 can be formed over the Ga-polar GaN layer 102 using any suitable techniques and may include aluminum-gallium-nitride (AlGaN), aluminum-nitride (AlN), indium-aluminum-nitride (InAlN), or scandium-aluminum-nitride (ScAlN). In some embodiments, the GaN layer 102 and the III-Nitride barrier layer 104 can include single-crystalline layers. In addition, in some embodiments, the initial structure 100 can be provided on a wafer 106. The wafer 106 can include a wafer of silicon, silicon-carbide, sapphire, GaN, AlN, diamond, or any other suitable wafer. As described in more detail below, the wafer 106 can include alignment marks 108. For simplicity, the optional wafer 106 and optional alignment marks 108 are not included in FIGS. 1B-D.

Referring to FIG. 1B, a polarity-switching layer 110 can be formed over the III-Nitride barrier layer 104 using any suitable techniques to form a structure 112. The polarity-switching layer 110 can include niobium nitride (NbN), tantalum nitride (TaN), or any suitable rare-earth nitride or other material configured to switch the polarity of a layer formed over the polarity-switching layer 110 from a first polarity to a second polarity. The polarity-switching layer 110 can include a single-crystalline layer.

Referring to FIG. 1C, the structure 112 can be patterned and etched to form one or more holes 114. In some embodiments, the structure 112 can be patterned and etched to form the holes 114 through the polarity-switching layer 110 and the III-Nitride barrier layer 104 and partially into the Ga-polar GaN layer 102. The holes 114 may be formed using any suitable patterning and etching techniques or other techniques. In some cases, by patterning and etching or otherwise forming both the III-Nitride barrier layer 104 and the polarity-switching layer 110 in a single step, these two layers 104 and 110 can be self-aligned after the holes 114 are etched.

Referring to FIG. 1D, a single layer 116 is formed inside the holes 114 and over the polarity-switching layer 110 to form a structure 118. In some embodiments, the single layer 116 can include a Group III-nitride, such as GaN or the like. In particular embodiments, the single layer 116 can include N+GaN. The N-Type dopant may include silicon, germanium, or other suitable N-type dopant. The single layer 116 can be formed using any suitable techniques. In some embodiments, the single layer 116 can be formed by molecular beam epitaxy. In these embodiments, the single layer 116 can be formed with line-of-sight growth such that a thickness of the single layer 116 is substantially consistent across the resulting structure 118.

The single layer 116 can include a first-polarity region 116a within the holes 114 and a second-polarity region 116b over the polarity-switching layer 110. Because the polarity-switching layer 110 can include a single-crystalline layer in which the single layer 116 is grown in the holes 114 over the Ga-polar GaN layer 102, the result is a single-crystalline first-polarity region 116a that has a first polarity. In contrast, where the single layer 116 is grown over the single-crystalline polarity-switching layer 110, the result is a single-crystalline second-polarity region 116b that has a second polarity. In this way, a single-crystalline second-polarity region 116b can be formed as a sacrificial layer that can be more easily removed as compared to a single-crystalline layer having the first polarity. In addition, this allows the first-polarity region 116a to remain after removal of the second-polarity region 116b.

In particular embodiments in which the single layer 116 includes GaN, the first-polarity region 116a within the holes 114 can include Ga-polar GaN, and the second-polarity region 116b over the polarity-switching layer 110 can include N-polar GaN. Thus, in these embodiments, single-crystalline N-polar GaN can be formed as a sacrificial layer that can be more easily removed as compared to a polycrystalline GaN layer, while allowing the Ga-polar GaN to remain after removal of the N-polar GaN.

Although FIGS. 1A-1D illustrate one example of a process of ohmic regrowth masking, various changes may be made to FIGS. 1A-1D. For instance, the structure 118 may include additional layers not shown in FIGS. 1A-1D. Also, the illustrated structure 118 including two holes 114 filled to form two first-polarity regions 116a can be used to construct, for example, a transistor. In some embodiments, the structure 118 can include one hole 114 filled to form one first-polarity region 116a that can be used to construct, for example, a diode. In addition, note that the views shown in FIGS. 1A-1D are not to scale.

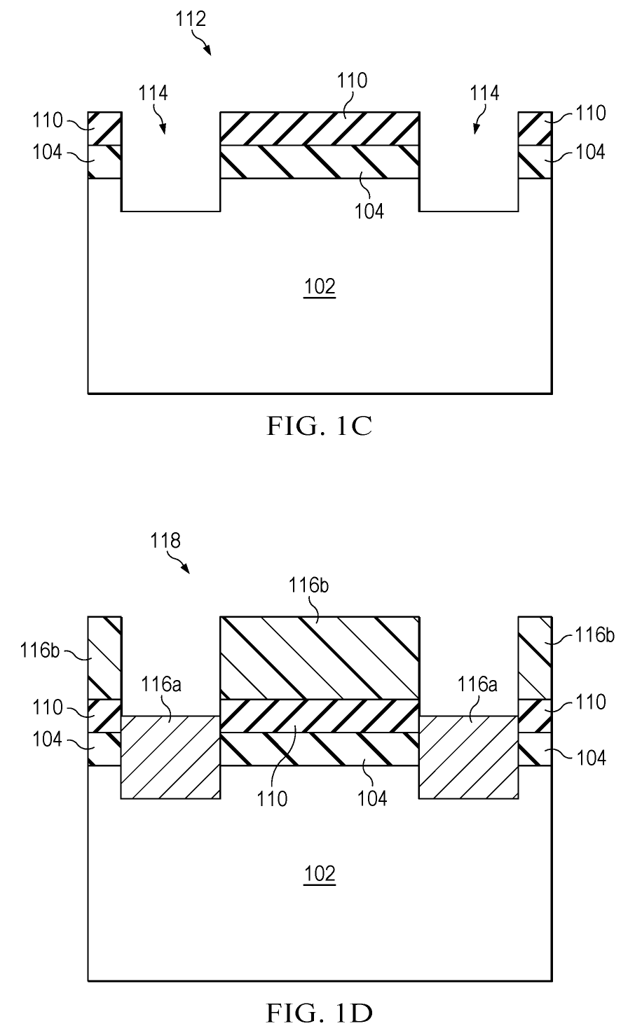

FIG. 2 is a schematic cross-sectional diagram illustrating an example structure 200 formed using ohmic regrowth masking according to this disclosure. The embodiment of the structure 200 shown in FIG. 2 is for illustration only. Other embodiments of the structure 200 may be used without departing from the scope of this disclosure.

According to embodiments of this disclosure, the structure 118 described above in connection with FIG. 1D may be etched using any suitable etching techniques to remove the second-polarity region 116b in order to form the structure 200. In embodiments in which the first-polarity region 116a includes Ga-polar GaN and the second-polarity region 116b includes N-polar GaN, the second-polarity region 116b may be removed using a wet etching technique. As N-polar GaN is several orders of magnitude more reactive than the Ga-polar GaN, a wet etch using any of a variety of acids or bases could be used. Thus, the N-polar GaN of the second-polarity region 116b may be easily removed, while the Ga-polar GaN of the first-polarity region 116a remains as part of the structure 200.

According to embodiments of this disclosure, the second-polarity region 116b may be etched using any suitable etching techniques selective to the material of the polarity-switching layer 110 as well as to the material of the first-polarity region 116a. In these embodiments, in addition to the first-polarity region 116a, the polarity-switching layer 110 also remains as part of the structure 200 after removal of the second-polarity region 116b. In some embodiments, the remaining polarity-switching layer 110 can be configured to form a bottom of a gate for the structure 200. In these embodiments, a separate alignment process can be avoided as the polarity-switching layer 110 is self-aligned with the second-polarity region 116b, which is removed to expose the remaining polarity-switching layer 110.

In some embodiments in which the initial structure 100 is provided on a wafer 106, a diffraction grating structure that is configured to allow alignment for a photolithography mask can be included elsewhere on the wafer 106 (not shown in FIG. 2). In these embodiments, TaN is typically used to pattern the diffraction grating structure, resulting in alignment marks 108 formed from TaN. For a conventional ohmic regrowth process using a dielectric hardmask, hydrofluoric acid (HF) is typically used to etch the dielectric hardmask. However, HF also etches TaN, which can result in unintentional etching of the alignment marks 108. In contrast, a non-HF-based etch process can be used to remove the second-polarity region 116b of the structure 200 of this disclosure without affecting any TaN alignment marks 108 elsewhere on the wafer 106. Thus, by avoiding the use of an HF-based process, TaN alignment marks 108, as well as any other parts of the wafer 106 that could be negatively affected by an HF etch, can be protected from unintentional etching.

Although FIG. 2 illustrates one example of a structure 200 formed using ohmic regrowth masking, various changes may be made to FIG. 2. For instance, the structure 200 may include additional layers not shown in FIG. 2. In addition, note that the view shown in FIG. 2 is not to scale.

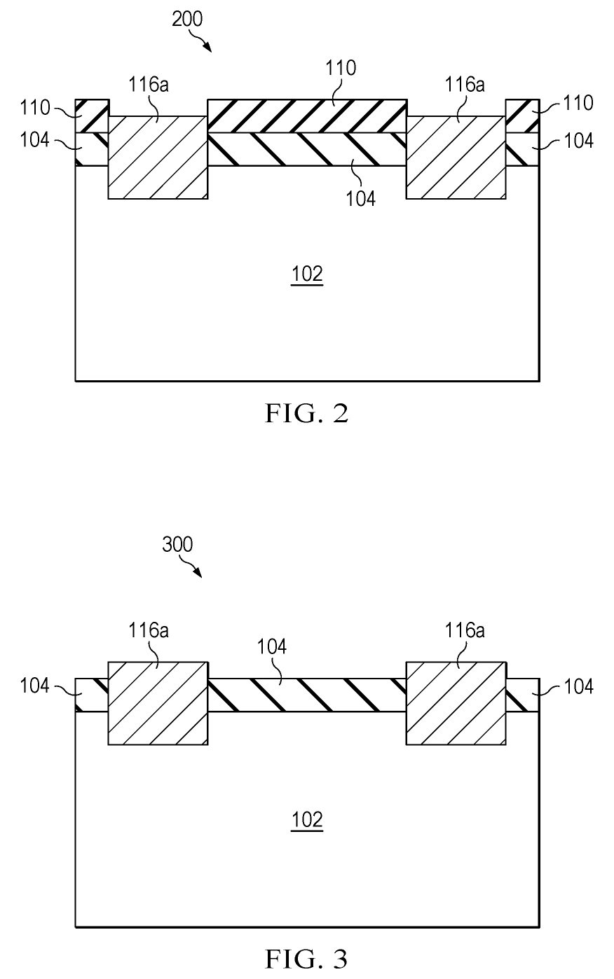

FIG. 3 is a schematic cross-sectional diagram illustrating another example structure 300 formed using ohmic regrowth masking according to this disclosure. The embodiment of the structure 300 shown in FIG. 3 is for illustration only. Other embodiments of the structure 300 may be used without departing from the scope of this disclosure.

According to embodiments of this disclosure, the structure 118 described above in connection with FIG. 1D may be etched to remove the second-polarity region 116b in order to form the structure 300. In embodiments in which the first-polarity region 116a includes Ga-polar GaN and the second-polarity region 116b includes N-polar GaN, the second-polarity region 116b may be removed using a wet etching technique. As N-polar GaN is several orders of magnitude more reactive than the Ga-polar GaN, a wet etch using any of a variety of acids or bases could be used. Thus, the N-polar GaN of the second-polarity region 116b may be easily removed, while the Ga-polar GaN of the first-polarity region 116a remains as part of the structure 300.

In addition, according to embodiments of this disclosure, the polarity-switching layer 110 can be removed to form the structure 300. In some embodiments, the second-polarity region 116b may be etched using any suitable etching techniques that also remove the polarity-switching layer 110. In other embodiments, after the second-polarity region 116b is removed, the polarity-switching layer 110 can also be removed using a separate wet etch or other suitable etch techniques.

In some embodiments in which the polarity-switching layer 110 includes TaN and the structure 300 is formed on a wafer 106, alignment marks 108 on the wafer 106 can include tantalum, titanium-tungsten, an etched mark or other suitable material that would not be removed by an etch process that removed the polarity-switching layer 110. In other embodiments, alignment marks 108 on the wafer 106 can include TaN. For these embodiments, a protective layer can be patterned above the alignment marks 108 to protect them from an etch process that would remove the polarity-switching layer 110, while leaving the polarity-switching layer 110 exposed for removal.

Although FIG. 3 illustrates another example of a structure 300 formed using ohmic regrowth masking, various changes may be made to FIG. 3. For instance, the structure 300 may include additional layers not shown in FIG. 3. In addition, note that the view shown in FIG. 3 is not to scale.

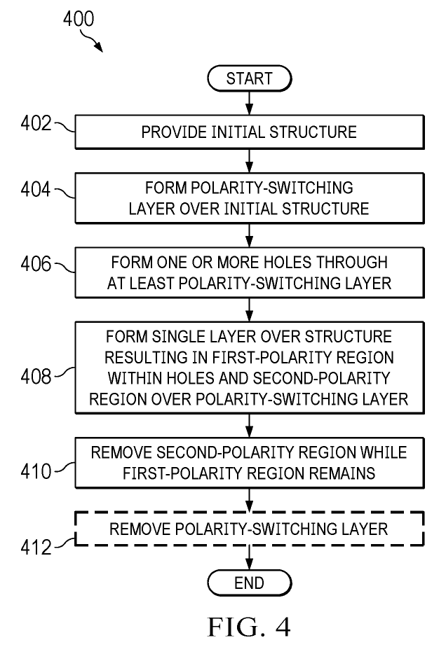

FIG. 4 illustrates an example of a method 400 for providing ohmic regrowth masking according to this disclosure. As shown in FIG. 4, an initial structure 100 is provided at step 402. This may include, for example, providing an initial structure 100 that includes a Ga-polar GaN layer 102 and a III-Nitride barrier layer 104. The III-Nitride barrier layer 104 may include, for example, aluminum-gallium-nitride (AlGaN), aluminum-nitride (AlN), indium-aluminum-nitride (InAlN), or scandium-aluminum-nitride (ScAlN). The III-Nitride barrier layer 104 may be formed over the Ga-polar GaN layer 102 using any suitable techniques. The GaN layer 102 and the III-Nitride barrier layer 104 can include single-crystalline layers. In some embodiments, the initial structure 100 can be provided on a wafer 106.

A polarity-switching layer 110 is formed over the initial structure 100 to form a structure 112 at step 404. This may include, for example, the polarity-switching layer 110 being formed over the III-Nitride barrier layer 104 using any suitable techniques. The polarity-switching layer 110 can include NbN, TaN, or any suitable rare-earth nitride or other material configured to switch the polarity of a layer formed over the polarity-switching layer 110 from a first polarity to a second polarity.

One or more holes 114 are formed through at least the polarity-switching layer 110 at step 406. This may include, for example, patterning and etching the structure 112 to form the holes 114. In some embodiments, the structure 112 can be patterned and etched to form the holes 114 through the polarity-switching layer 110 and the III-Nitride barrier layer 104 and partially into the Ga-polar GaN layer 102 (or subset). The holes 114 may be formed using any suitable patterning and etching techniques or other techniques. By forming the holes 114 through both the III-Nitride barrier layer 104 and the polarity-switching layer 110 in a single step, these two layers 104 and 110 can be self-aligned after the holes 114 are etched.

A single layer 116 is formed over the structure 112 to form a structure 118 at step 408. This may include, for example, forming a single layer 116 including a first-polarity region 116a within the holes 114 and a second-polarity region 116b over the polarity-switching layer 110. In some embodiments, this may include forming a single layer 116 that includes GaN, resulting in a first-polarity region 116a within the holes 114 that includes Ga-polar GaN and a second-polarity region 116b over the polarity-switching layer 110 that includes N-polar GaN. In particular embodiments, the single layer 116 can include N+GaN. The N-Type dopant may include silicon, germanium, or other suitable N-type dopant. In addition, in some embodiments, the single layer 116 can be formed by molecular beam epitaxy or any other suitable techniques. In particular embodiments, the single layer 116 can be formed with line-of-sight growth such that a thickness of the single layer 116 is substantially consistent across the resulting structure 118.

The second-polarity region 116b is removed from the structure 118, while the first-polarity region 116a formed in the holes 114 remains, to form a structure 200 at step 410. The second-polarity region 116b may be removed using any suitable techniques, such as a suitable wet etching process. In embodiments in which the single layer 116 includes GaN, the first-polarity region 116a includes Ga-polar GaN, and the second-polarity region 116b includes N-polar GaN, a wet etch using any of a variety of acids or bases could be used as N-polar GaN is several orders of magnitude more reactive than the Ga-polar GaN. Thus, the N-polar GaN may be easily removed, while the Ga-polar GaN remains as part of the structure 200. In some embodiments, the N-polar GaN of the second-polarity region 116b may be etched using any suitable etching techniques selective to the material of the polarity-switching layer 110 as well as the Ga-polar GaN of the first-polarity region 116a. In these embodiments, in addition to the first-polarity region 116a, the polarity-switching layer 110 also remains as part of the structure 200 after removal of the second-polarity region 116b. In particular embodiments, the remaining polarity-switching layer 110 can be part of a gate for the structure 200.

The polarity-switching layer 110 can be removed to form a structure 300 at optional step 412. This may include, for example, removing the second-polarity region 116b at step 410 using any suitable etching techniques that also removes the polarity-switching layer 110 but that is selective to the first-polarity region 116a and the III-Nitride barrier layer 104. This may also include performing a separate etch process to remove the polarity-switching layer 110 after removing the second-polarity region 116b at step 410.

Thus, by implementing an ohmic regrowth masking process that includes a polarity-switching layer, the use of a dielectric hardmask becomes unnecessary. In this way, the need for a long liftoff-based etch to remove unwanted polycrystalline GaN formed over a dielectric hardmask can be eliminated, resulting in a much quicker process as compared to the conventional process involving a dielectric hardmask. Also, unintentional etching of other components of a wafer 106 that includes the structure 200 or 300, such as alignment marks 108, can be prevented. In addition, when the polarity-switching layer 110 is retained as part of a gate structure, for example, self-alignment is provided based on the second-polarity region 116b being formed in alignment with the polarity-switching layer 110.

Although FIG. 4 illustrates one example of a method 400 for providing ohmic regrowth masking, various changes may be made to FIG. 4. For example, while shown as a series of steps, various steps in FIG. 4 may overlap, occur in parallel, occur in a different order, or occur any number of times (including zero times).

It may be advantageous to set forth definitions of certain words and phrases used throughout this patent document. The term “about” (when used with a numerical value) indicates that the numerical value may vary by up to ±10%. The terms “include” and “include,” as well as derivatives thereof, mean inclusion without limitation. The term “or” is inclusive, meaning and/or. The phrase “associated with,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

The description in the present disclosure should not be read as implying that any particular element, step, or function is an essential or critical element that must be included in the claim scope. The scope of patented subject matter is defined only by the allowed claims. Moreover, none of the claims invokes 35 U.S.C. § 116(f) with respect to any of the appended claims or claim elements unless the exact words “means for” or “step for” are explicitly used in the particular claim, followed by a participle phrase identifying a function. Use of terms such as (but not limited to) “mechanism,” “module,” “device,” “unit,” “component,” “element,” “member,” “apparatus,” “machine,” “system,” “processor,” or “controller” within a claim is understood and intended to refer to structures known to those skilled in the relevant art, as further modified or enhanced by the features of the claims themselves, and is not intended to invoke 35 U.S.C. § 116(f).

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. A method comprising:
forming a single gallium-nitride (GaN) layer over a structure, the structure comprising a polarity-switching layer and at least one hole through at least the polarity-switching layer, the single GaN layer comprising a nitrogen-polar (N-polar) GaN region over the polarity-switching layer and comprises a gallium-polar (Ga-polar) GaN region within the at least one hole; and
removing the N-polar GaN region from the structure while the Ga-polar GaN region remains.

2. The method of claim 1, wherein the polarity-switching layer comprises niobium nitride (NbN) or tantalum nitride (TaN).

3. The method of claim 1, wherein the GaN layer comprises N+GaN doped with silicon or germanium.

4. The method of claim 1, wherein removing the N-polar GaN region comprises removing the N-polar GaN region by a wet etching process.

5. The method of claim 1, further comprising removing the polarity-switching layer.

6. The method of claim 1, wherein:
the structure is formed on a wafer;
the wafer comprises alignment marks; and
removing the N-polar GaN region from the structure further comprises removing the N-polar GaN region without etching the alignment marks.

7. A method comprising:
providing an initial structure;
forming a polarity-switching layer over the initial structure;
forming at least one hole through at least the polarity-switching layer; and
forming a single layer comprising a specified material within the at least one hole and over the polarity-switching layer;
wherein the specified material comprises a first polarity within the at least one hole and a second polarity over the polarity-switching layer; and
wherein the specified material comprising the second polarity is configured to be selectively removable without affecting the specified material comprising the first polarity.

8. The method of claim 7, wherein the polarity-switching layer comprises niobium nitride (NbN) or tantalum nitride (TaN).

9. The method of claim 7, wherein the specified material comprises a Group III-nitride.

10. The method of claim 9, wherein the Group III-nitride comprises gallium-nitride (GaN).

11. The method of claim 10, wherein the first polarity comprises gallium-polar (Ga-polar) and the second polarity comprises nitrogen-polar (N-polar).

12. The method of claim 9, wherein the Group III-nitride comprises N+GaN doped with silicon or germanium.

13. The method of claim 7, further comprising removing the specified material that comprises the second polarity by a wet etching process.

14. The method of claim 7, further comprising removing the polarity-switching layer.

15. The method of claim 7, wherein:
providing the initial structure comprises providing the initial structure on a wafer;
the wafer comprises alignment marks; and
the specified material comprising the second polarity is further configured to be selectively removable without etching the alignment marks.

16. A structure comprising:
a gallium-polar (Ga-polar) gallium-nitride (GaN) layer formed on a wafer;
a III-Nitride barrier layer formed over the Ga-polar GaN layer;
a polarity-switching layer formed over the III-Nitride barrier layer;
at least one hole formed through at least the polarity-switching layer; and
a single layer formed within the at least one hole and over the polarity-switching layer, wherein the single layer comprises a first-polarity region within the at least one hole and a second-polarity region over the polarity-switching layer.

17. The structure of claim 16, wherein the single layer comprises a Group III-nitride.

18. The structure of claim 16, wherein the single layer comprises GaN, the first-polarity region comprises Ga-polar GaN, and the second-polarity region comprises nitrogen-polar (N-polar) GaN.

19. The structure of claim 18, wherein the single layer further comprises N+GaN doped with silicon or germanium.

20. The structure of claim 16, wherein the polarity-switching layer comprises niobium nitride (NbN) or tantalum nitride (TaN).
